(19) United States
(12) Patent Application Publication
(10) Pub. No.: US 2002/0185712 A1
(43) Pub. Date: Dec. 12, 2002

(54) Circuit encapsulation technique utilizing electroplating

(76) Inventors: Brian Stark, Ann Arbor, MI (US); Khalil Najafi, Ann Arbor, MI (US)

Correspondence Address: HARNESS, DICKEY & PIERCE, P.L.C., P.O. BOX 828, BLOOMFIELD HILLS, MI, 48303, US

(21) Appl. No.: 10/163,292

(22) Filed: Jun. 5, 2002

Related U.S. Application Data
(60) Provisional application No. 60/297,225, filed on Jun. 8, 2001.

(51) Int. Cl. H01L 21/4763

(52) U.S. Cl. 257/642; 257/632; 257/643; 257/644; 438/622; 438/623

(57) ABSTRACT

A novel technology is provided for encapsulating electronics for use in harsh media applications, such as biomedical implants. The present invention includes electroplating a metal film on top of an insulating layer to hermetically seal an electronic system, microstructure, or micro device.

### CROSS-REFERENCE TO RELATED APPLICATIONS

This application claims the benefit of U.S. Provisional Application No. 60/297,225, filed Jun. 8, 2001.

### STATEMENT OF GOVERNMENTAL SUPPORT

This invention was made with Government support under Grant No. NIH-NINDS-N01-NS-8-2387 awarded by the National Institute of Health, and Grant No. EEC-9986866 awarded by the National Science Foundation. The Government has certain rights in this invention.

### FIELD OF THE INVENTION

The present invention relates to hermetic packages and, more particularly, relates to an electroplated, hermetically-sealed, electrical package.

### BACKGROUND OF THE INVENTION

Recently, there has been a growing trend to develop miniature hermetic packages for protection of micro-electro-mechanical-systems (MEMS) and integrated circuitry from harsh external environments. In implantable biomedical applications, it is important to develop biocompatible packages that insulate the MEMS and integrated circuitry within the system from the biological environment. Without any reliable protection method, top layer thin-film dielectrics, such as silicon dioxide, silicon nitride, or polymers, will break down in biological environments. Furthermore, these biocompatible packages must meet strict size limitations enforced by the demands of the biological environment. As a result, the package must not only be hermetic, it must also have a small size and be low profile.

In the past, long-term hermetic biopackaging has been demonstrated extensively by anodic bonding of glass to polysilicon, by encapsulation with silicone rubber, and by encapsulation with Parylene-C. However, techniques that utilize wafer bonding are hampered by the need for planarization techniques to improve bond quality. Furthermore, these methods are also limited by the material and temperature requirements of implantable electronics. Implantable systems also require biocompatible packaging materials, which limit the use of many lead-based glasses and solders traditionally used in wafer bonding. The low thermal budget of processed electronics prevents other bonding techniques, such as fusion bonding, from being a useful packaging approach. Other methods of biopackaging have relied upon organic films for protection. However, these organic films often break down during accelerated tests and may not be optimized as a hermetic barriers to moisture. As a result, it is difficult to predict package lifetimes.

Recently, implantable devices have been manufactured in silicon substrates. These devices require packages integrated at the wafer level in order for them to have both a functional viability and an economic viability.

Accordingly, there exists a need in the relevant art to provide a method of hermetically sealing a package that doesn't readily break down in biological environments. Furthermore, there exists a need in the relevant art to provide a method of hermetically sealing a package that effectively prevents infiltration of moisture. Still further, there exists a need in the relevant art to provide a hermetic package that overcomes the disadvantages of the prior art.

### SUMMARY OF THE INVENTION

According to the principles of the present invention, a novel technology is provided for encapsulating electronics for use in harsh media applications, such as human body implants. The present invention is a method that includes electroplating a thick metal film on top of an insulating layer to fully encapsulate and hermetically seal a system. More particularly, a dielectric layer, such as polyimide, glass, SiO₂, or polymer, is deposited on top of an integrated circuit which is integrated onto a wafer. The polyimide layer (or other insulating dielectric layer) is then photolithographically patterned and removed from the field region and left over the integrated circuit or device region that is to be protected. A metal film is then sputter deposited on top of the dielectric layer (or the wafer). A photo-resist mold is then deposited on the wafer and developed using standard lithography. This wafer is then placed into an electroplating station. In areas on the wafer covered with photo-resist, no plating will occur. In the exposed areas, a relatively thick electroplated film will form (the thickness of this film can be varied according to specific application areas). The photo-resist mold is then stripped in a wet chemical bath, or in a dry etching apparatus, and the image of the mold is reversed to cover the plated film. The sputtered layer is then removed in wet or dry chemicals to remove or at least neutralize the chemical etchants that typically attack a sputtered layer, which may reduce the hermeticity of the plated film.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view illustrating an ultra-thin hermetic biocompatible package according to the principles of the present invention;

FIG. 2 is an enlarged, partial cutaway, perspective view illustrating the ultra-thin hermetic biocompatible package according to the principles of the present invention;

FIG. 3 is a graph illustrating the time for package interior to reach 50% of exterior humidity of various materials;

FIG. 4 is a perspective view illustrating self-induced galvanic bias to reduce silicon dissolution according to the principles of the present invention;

FIG. 5 is a perspective view illustrating a packaged implantable probe;

FIGS. 6(a)-(d) is a series of schematic cross-sectional views illustrating the process step of fabricating the hermetic biocompatible package of the present invention;

FIG. 7 is an enlarged, partial cutaway, perspective view illustrating the electroplated outer layer and dielectric layer;

FIG. 8 is a perspective view illustrating an integrated leak detector circuit;

FIG. 9 is a plan view illustrating the integrated leak detector circuit;

FIGS. 10(a)-(f) is a series of schematic cross-sectional views illustrating the process step of fabricating the leak detector circuit; and

FIG. 11 is a dynamic response graph illustrating the output of the leak detector circuit when immersed in PBS at 95° C.

### DETAILED DESCRIPTION OF THE PREFERRED EMBODIMENTS

The following description of the preferred embodiments is merely exemplary in nature and is in no way intended to limit the invention, its application, or uses.

Generally, the present invention relates to planar, photolithographically-defined micro-electro-mechanical systems (MEMS) for implantable biomedical applications. To this end, the present invention defines a new method of packaging implantable electronics employing a thin film of polyimide, or other insulator, encased in electroplated gold. The insulator insulates the electronics in the circuit from the gold layer. The method of the present invention differs from previous work in that it employs and/or produces hermetic packages at the wafer level and does not require bonding, high temperatures, or large electric fields that may potentially damage electronic circuitry. An additional advantage of the present invention is that the thickness of the entire implantable system can be reduced to less than 50 microns, which dramatically improves its usability in biomedical applications.

As mentioned, the present invention is particularly useful in the encapsulation of integrated circuits for implantable devices. However, it should D be readily understood that the principles of the present invention may find utility in a wide variety of applications. Therefore, although the following describes the preferred embodiment, its disclosure should not be construed to limit the scope of protection.

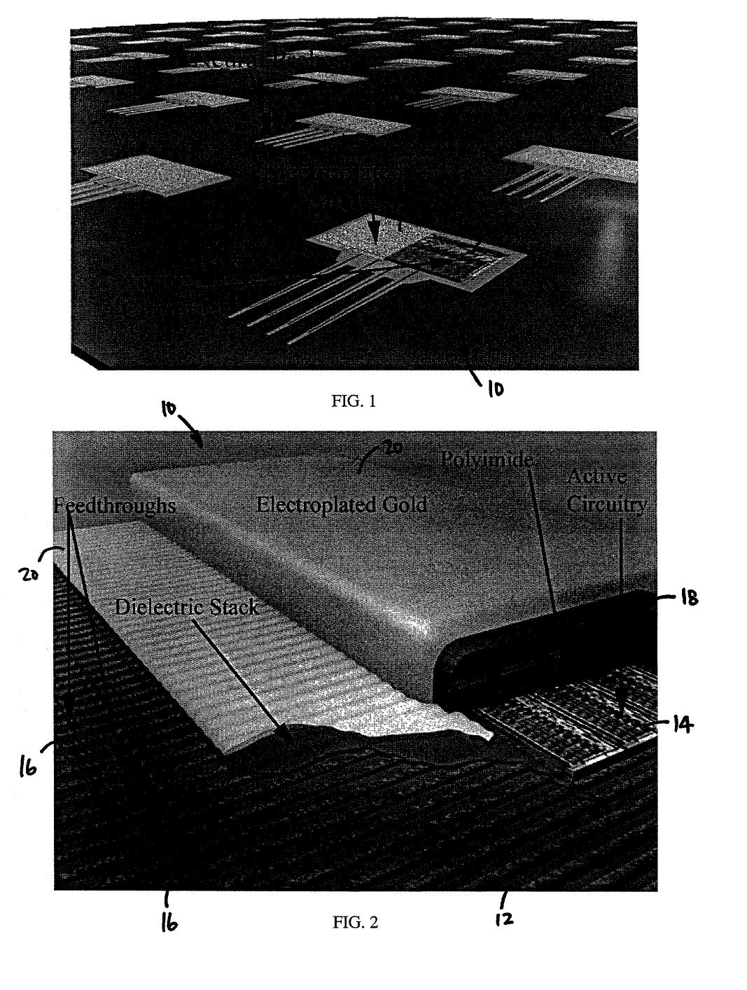

With particular reference to FIGS. 1 and 2, an ultra-thin hermetic biocompatible package 10 is illustrated according to the principles of the present invention as applied to implantable silicon microprobes with on-chip circuitry. Hermetic biocompatible package 10 generally includes a silicon microprobe substrate 12, a micro device or circuit 14, a plurality of electrical connects 16, a dielectric layer or insulator 18, and an electroplated gold shield or outer layer 20 to create chronically implantable devices with active electronic components.

As seen in FIG. 1, electrical connects 16 are preferably formed by running insulated polysilicon lines underneath electroplated outer layer 20. Since electroplated outer layer 20 is deposited on and conforms to electrical connects 16, there is no need for any special planarization steps.

Dielectric layer 18 insulates the electronics in circuit 14 from electroplated outer layer 20. Selection of the material for dielectric layer 18 is critical to the effectiveness of hermetic biocompatible package 10. It should be noted that dielectric layer 18 may be made from a number of materials, such as any insulating in-organic film, polyimide, glass, SiO₂, or polymer. However, the thickness and dielectric constant of dielectric layer 18 will determine the parasitic capacitance of circuit 14 to electroplated outer layer 20, which may limit the frequency response of circuit 14. Preferably, dielectric layer 18 should demonstrate good adhesion to metal and cure at a temperature that is lower than the thermal budget of the remaining process steps to prevent bubbling of dielectric layer 18. In the present embodiment, it is preferable that dielectric layer 18 is polyimide because of its low dielectric constant and its ease of being spun cast into a thick film that cures above 350° C.

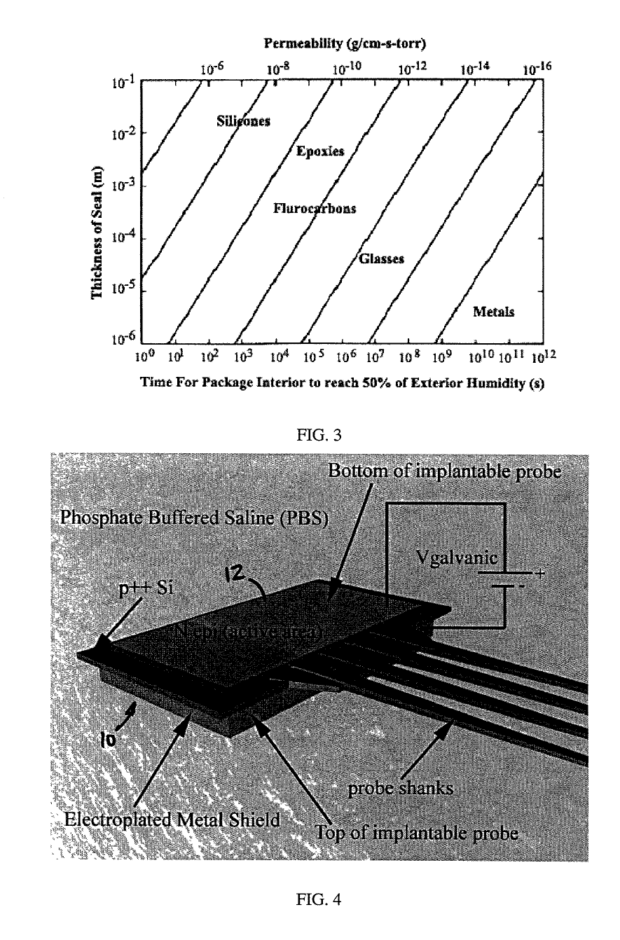

Electroplated outer layer 20 is used to encapsulate at least a portion of silicon microprobe substrate 12, circuit 14, electrical connects 16, and dielectric layer 18 to provide a thick hermetic barrier to penetrating moisture. Metals are preferably chosen due to their high density and, thus, excellent performance as hermetic barriers. With particular reference to FIG. 3, it can be seen that metal films are substantially more resistant to moisture penetration than films of other materials of comparable thickness. Selection of the proper metal film for electroplated outer layer 20 depends upon several factors. For instance, it has been found that silicon will etch when exposed to a Phosphate Buffered Saline (PBS) solution, which is used to simulate body conditions at elevated temperature in laboratory settings. This 7.4 pH solution exhibits etch characteristics that are similar to Ethylene Diamine Pyrocatechol (EDP), Tetramethylammonium hydroxide (TMAH), and Potassium Hydroxide (KOH), albeit at a much slower rate. In extended implants of thin silicon devices, this etch rate cannot be ignored as it creates a mechanisms for failure through dissolution of the silicon beneath the active electronics. Since both the silicon of the implantable device and the metal shield form the structure of the package, the long-term reliability of both materials must be considered in package design. Accordingly, it is preferable that outer layer 20 is gold due to its ease of electroplating, high density, and biocompatibility properties.

On the other hand, to mitigate the dissolution of silicon, two corrosion reduction techniques have been developed. One approach involves a degenerately boron-doped etch stop while the other utilizes an in-situ self-induced galvanic bias of the silicon. Given that it is impractical to implement a degenerately boron-doped layer beneath the active electronics of an implantable system, the self-induced galvanic bias technique should be used to reduce the corrosion of silicon in long-term implants. We have found that an Au—Si battery potential reduces the dissolution of silicon by three orders of magnitude in PBS, which again makes gold a preferred choice for encapsulating dielectric layer 18 in hermetic biocompatible package 10. FIG. 4 illustrates the mechanism by which a galvanic bias is implemented on substrate 12 using a PBS solution and applying a voltage to effect such electroplating. Gold is thus selected as the metal layer to encapsulate dielectric layer 18 for its galvanic properties as well as its ease of electroplating, high density, inertness, and biocompatibility.

For any packaging technology, some of the most important factors are reliability and manufacturability. That is, in order for a technology to demonstrate its practicality, it must be capable of being reproducibly made and have a lifetime greater than the device it encapsulates. This is particularly important in one of the potential applications of the present invention-encapsulation of neural prostheses for chronic implants. These devices have been proposed for the treatment of nervous system impairment and may need to be implanted for the entire lifetime of a young patient. As a result, the package will need to maintain hermeticity for greater than 50 years.

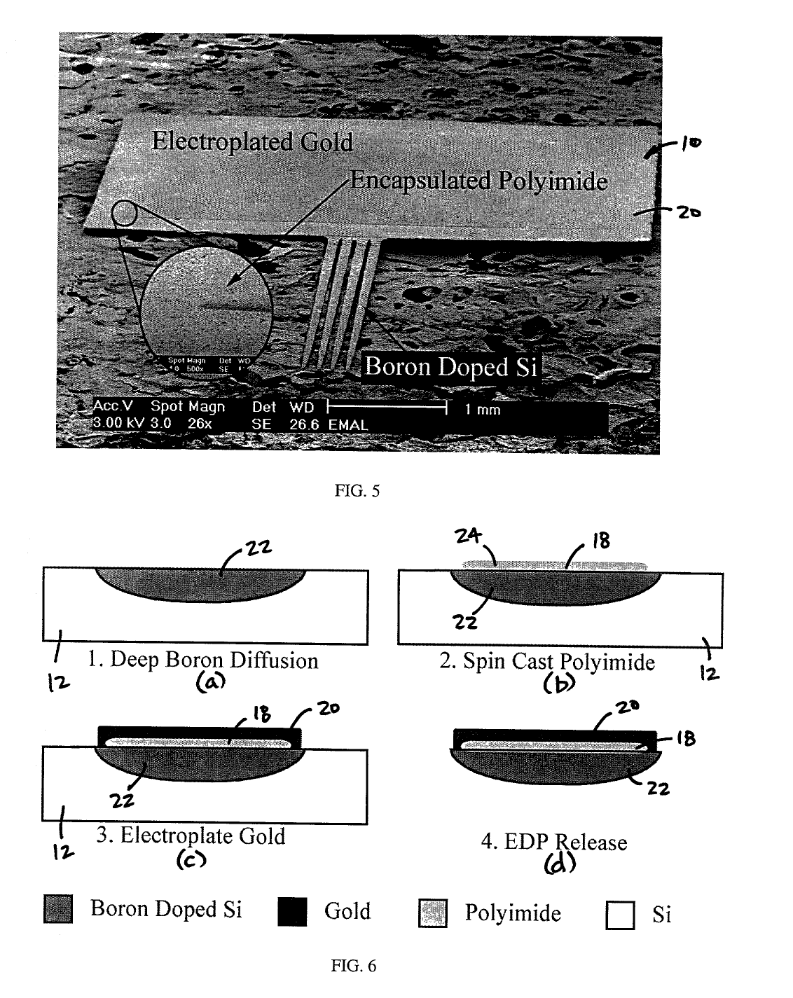

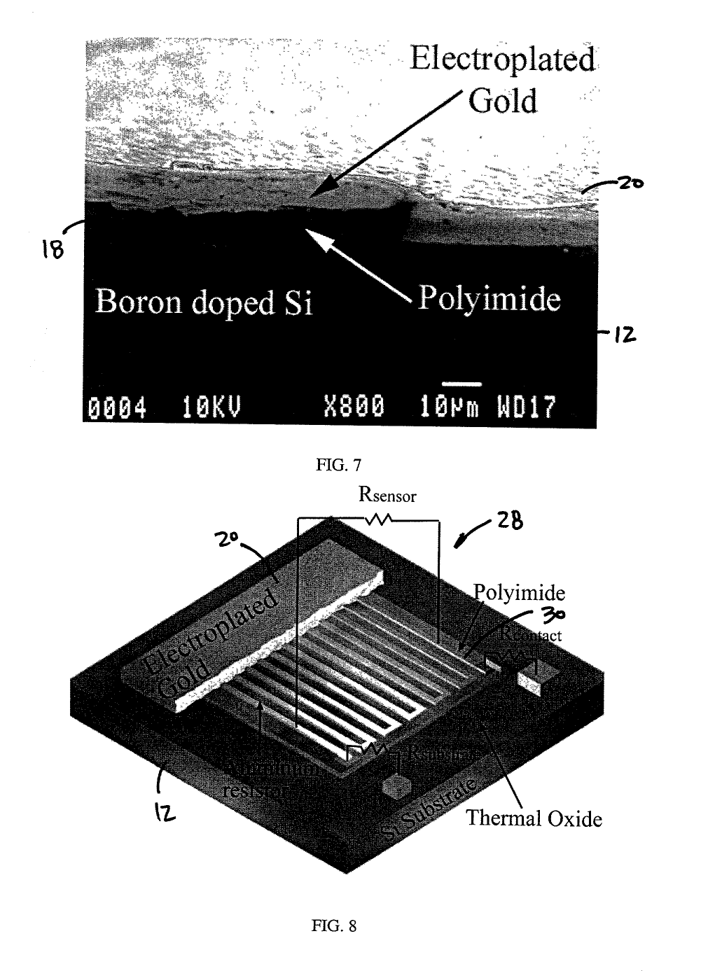

Therefore, in order to demonstrate the initial effectiveness of hermetic biocompatible package 10, an implantable probe substrate with a 3 mm×5 mm back end, illustrated in FIG. 5, was fabricated to serve as a test structure. As seen in FIG. 6, the process flow for producing the test structure is illustrated. In the preferred device, active circuitry 14 would be placed in a lightly-doped region on the back end of the probe as indicated in FIG. 1. With particular reference to FIG. 6(a), the implantable probe substrate 12 is first defined using deep boron diffusion 22. In FIG. 6(b), a 2-micron thick layer of P12611 polyimide 24 is then spin casted to form dielectric layer 18. Next, a 500 Å Cr/5000 Å Au plating base is sputtered. Subsequently, in FIG. 6(c), a 3-micron thick gold film is electroplated from a cyanide-based solution through a photoresist mold to cover dielectric layer 18 and form electroplated outer layer 20. A negative photoresist is then used to invert the image of the plating mold to protect the gold during the removal of the plating base. The sputtered Cr/Au plating base is then removed in a wet etch. If electroplated outer layer 20 is not protected during the removal of the sputtered Cr/Au plating base, the hermeticity of electroplated outer layer 20 will be adversely impacted. At this point in the process, the probes are fully packaged at the wafer level. The final step, illustrated in FIG. 6(d), is to perform a dissolved wafer release with EDP at 110° C., an anisotropic silicon etchant that exhibits an excellent etch stop on boron-doped silicon and gold. When viewed in cross section, FIG. 7 illustrates dielectric polyimide layer 18 being encapsulated by electroplated gold outer layer 20.

Initial designs of hermetic biocompatible package 10 also used AZ4400 photoresist and Shipley 1827 as dielectric spacers. However it was discovered that photoresist tends to readily outgas when exposed to temperatures around 110° C. even when hard baked for extended periods. The material outgassing from the photoresist will exert a pressure on the gold film sufficient to rupture it, causing hermetic failure. As a result, attempts to utilize photoresist for insulating spacers were abandoned, as it cannot meet the necessary reliability requirements of this project. It is possible to use materials other than polyimide for hermetic biocompatible package 10. Thick layers of evaporated glass would meet all of the necessary requirements of this process. Other dielectrics, such as Parylene and BCB would also be suitable, provided they demonstrate good adhesion to chromium. These materials may in fact be preferable to polyimide in that they could potentially trap less moisture than polyimide.

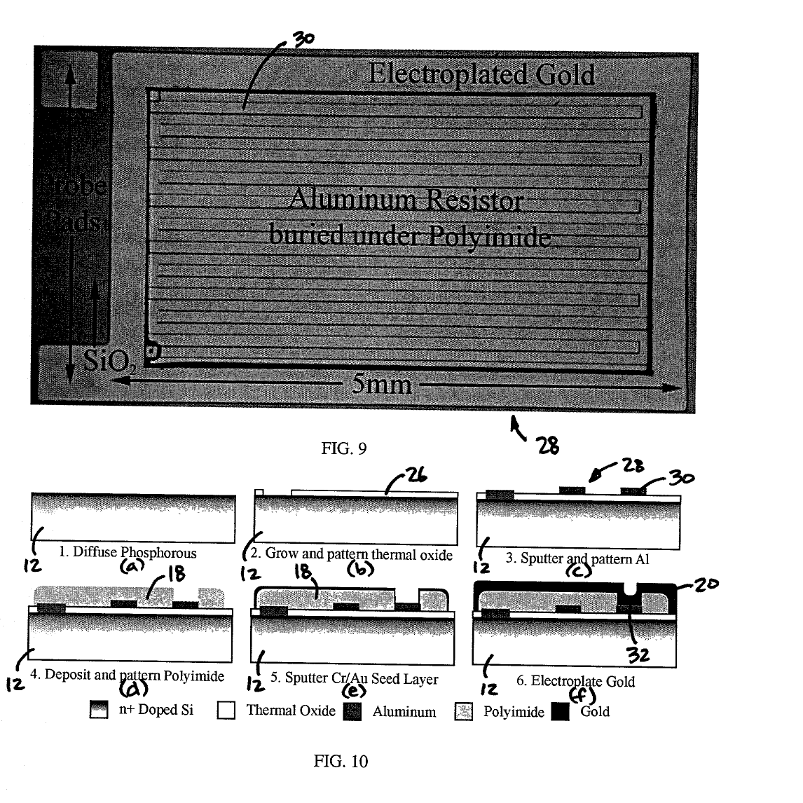

To test the chronic hermeticity of hermetic biocompatible package 10, a test structure was developed as illustrated in FIGS. 8 and 9. The fabrication process for this structure is set forth in FIG. 10. Specifically, as seen in FIGS. 10(a) and (b), a bare silicon wafer 12 is first degenerately doped with phosphorous and then a 5000 Å thick layer of thermal SiO₂ 26 is grown and patterned thereon. As seen in FIG. 10(c), a 5000 Å layer of aluminum is then sputtered deposited and patterned such that it forms an integrated leak detector circuit 28. This integrated leak detector circuit 28 consists of twelve series-connected aluminum sections 30 that are approximately 4.7 mm long by 100 μm wide.

Leak detector circuit 28 operates through a reliable mechanism. That is, when soaked in a corrosive solution, aluminum sections 30 will quickly etch, altering the resistance of circuit 28. These resistors are connected in series to make the test a binary measurement of package hermeticity. One end of the resistor contacts the conductive substrate 12 beneath thermal SiO₂ 26 while the other end of the resistor contacts electroplated outer layer 20 through dielectric layer 18 at via 32 (FIG. 10(f)). A parallel connection of the strips can indicate the degree to which moisture has penetrated the package, but for this application, any penetration is unacceptable. Once fabricated, the resistor is packaged in a layer of 5-micron thick P12731 photodefinable polyimide 18 that is encapsulated with 3-micron thick electroplated gold outer layer 20. The thicker, photodefinable, polyimide 18 is chosen for ease of processing and to reduce parasitic capacitance in future applications.

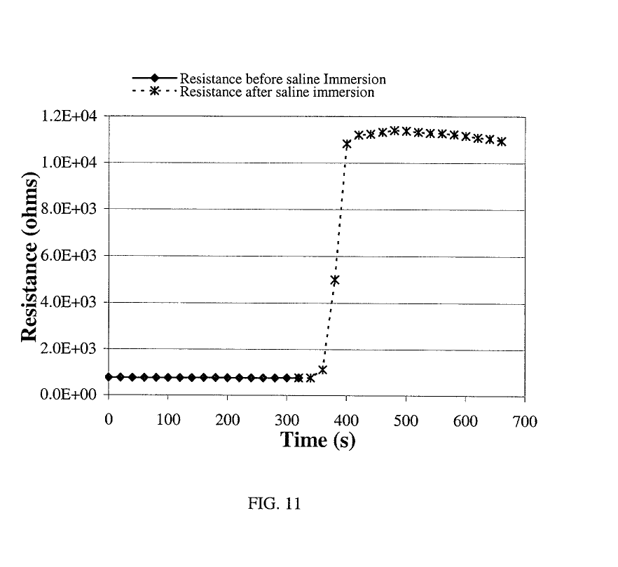

Leak detector circuit 28 was placed it in a PBS solution at 95° C. and the resistance across the terminals was measured. To perform this test, a fully packaged hermetic biocompatible package 10 was cut with a razor blade, removing the gold 20 and polyimide 18, while keeping the resistor intact. Leak detector circuit 28 was then glued to a metal hybrid package and a LABVIEW program was used to monitor resistance at 20-second intervals. The PBS solution was preheated for 3 hours to raise the temperature to 95° C. and the program was then started. After 360 seconds, leak detector circuit 28 was placed in the PBS solution. FIG. 11 illustrates the dynamic response of leak detector circuit 28 to the PBS solution. After 40 seconds, there is a marked rise in resistance from 720Ω to 11 kΩ. This is close to the contact resistance of the PBS solution, which is substantially lower than the open circuit resistance. When leak detector circuit 28 is removed from the PBS solution, resistance is immeasurable.

According to a second embodiment of the present invention, a second set of packages was fabricated using a modified design both to try to minimize any failures and to improve the quality of the reliability data. The new set of packages was manufactured with sputtered SiO₂ as a dielectric spacer instead of polyimide. This inorganic film has been chosen to try to reduce the potential for outgassing or moisture trapping. While the deposition rate of sputtered SiO₂ is too low to ultimately be implemented in a useful product, it is envisioned that this film can be made much thicker by using an intermediate layer of evaporated glass, which will increase thickness without decreasing adhesion quality. Lifetime tests were conducted to measure the MTTF of 72 packaged saline sensors with SiO₂ as the dielectric. To further improve the quality of the tests, new stations were devised that utilize incubating dry baths to control heat. These stations, which can control temperature to within 0.1° C., offer a marked improvement over the ovens previously used.

Packages with a sputtered SiO₂ dielectric performed worse than the devices with polyimide, with a shorter mean-time-to-failure (MTTF) at each temperature. The extracted MTTF at 37.5° C. for this design has been determined to be about 30 years. Failed packages with sputtered SiO₂ dielectrics showed no bubbling.

According to the principles of the present invention, a novel packaging technology based upon electroplated gold and polyimide is provided. The package utilizes a 3-micron thick polyimide layer encapsulated with 3 microns of gold. This technique is effective at hermetically sealing an implantable system. Furthermore, a novel integrated saline sensor that utilizes a thin metal film that is easily etched to measure moisture infusion into the package. This sensor readily lends itself to automated testing; through its use, we have shown preliminary data that suggests a mean time to failure at body temperature of 30 years.

The present invention has several important advantages. Since it utilizes a metal film, it can electromagnetically shield devices. This has applications in communications and military markets. Because the electroplating process is performed at the wafer level, it is possible to construct shielded packages at a fraction of the current cost. Expensive packages are a bottleneck in the production of many types of electronics. By integrating a hermetic, shielded package at the wafer level, it is possible to allow previously expensive circuits to be package in cheap non-hermetic plastic packages, which should substantially reduce cost.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method of hermetically sealing a system comprising:
providing a substrate having a micro device;
applying a dielectric layer over said micro device on said substrate; and
electroplating an outer layer over said dielectric layer so as to hermetically seal said micro device between said dielectric layer and said substrate.

2. The method according to claim 1 wherein said applying a dielectric layer over said micro device on said substrate includes applying a polymer over said micro device.

3. The method according to claim 1 wherein said applying a dielectric layer over said micro device on said substrate includes applying polyimide over said micro device.

4. The method according to claim 1 wherein said applying a dielectric layer over said micro device on said substrate includes applying glass over said micro device.

5. The method according to claim 1 wherein said applying a dielectric layer over said micro device on said substrate includes applying silicon oxide over said micro device.

6. The method according to claim 1 wherein said electroplating an outer layer over said dielectric layer includes electroplating a metal over said dielectric layer.

7. The method according to claim 1 wherein said electroplating an outer layer over said dielectric layer includes electroplating gold over said dielectric layer.

8. The method according to claim 1 wherein said substrate is silicon.

9. The method according to claim 1, further comprising:
forming a dielectric spacer between said dielectric layer and said substrate to provide a gap between said micro device and said substrate.

10. The method according to claim 1 wherein said micro device is an integrated circuit.

11. A method of hermetically sealing an implantable biomedical device, said method comprising:
providing a substrate having an integrated circuit;
applying a dielectric layer over said integrated circuit on said substrate; and
electroplating a metal outer layer over said dielectric layer so as to hermetically encapsulate said integrated circuit between said dielectric layer and said substrate.

12. The method according to claim 11 wherein said applying a dielectric layer over said integrated circuit on said substrate includes applying a dielectric chosen from a group consisting essentially of a polymer, polyimide, glass, and silicon oxide over said integrated circuit.

13. The method according to claim 11 wherein said electroplating said metal outer layer over said dielectric layer includes electroplating gold over said dielectric layer.

14. The method according to claim 11 wherein said substrate is silicon.

15. The method according to claim 11, further comprising:
forming a dielectric spacer between said dielectric layer and said substrate to provide a gap between said integrated circuit and said substrate.

16. A device comprising:
a substrate having an integrated circuit;
a dielectric layer disposed over said integrated circuit on said substrate; and
an electroplated metal outer layer disposed over said dielectric layer so as to hermetically seal said integrated circuit between said dielectric layer and said substrate.

17. The device according to claim 16 wherein said dielectric layer is chosen from a group consisting essentially of a polymer, polyimide, glass, and silicon oxide.

18. The device according to claim 16 wherein said electroplated metal outer layer is gold.

19. The device according to claim 16, further comprising:
a dielectric spacer disposed between said dielectric layer and said substrate to insulate between said integrated circuit and said substrate.

20. The device according to claim 16, further comprising:
a leak detection circuit formed with said substrate, said leak detection circuit having a plurality of etchable conductive strips defining a resistance, said plurality of etchable conductive strips being operable to alter said resistance upon detection of a leak.
